(19) United States
(12) Patent Application Publication
(10) Pub. No.: US 2012/0267724 A1
(43) Pub. Date: Oct. 25, 2012

(54) MOS SEMICONDUCTOR DEVICE AND METHODS FOR ITS FABRICATION

(75) Inventor: Suresh VENKATESAN, Danbury, CT (US)

(73) Assignee: GLOBALFOUNDRIES INC., Grand Cayman (KY)

(21) Appl. No.: 13/091,003

(22) Filed: Apr. 20, 2011

(51) Int. Cl. H01L 29/78; H01L 21/336

(52) U.S. Cl. 257/402; 438/289; 257/E21.409; 257/E29.255

(57) ABSTRACT

An MOS device having a selectively formed channel region and methods for its fabrication are provided. One such method includes forming a mask defining a gate region overlying a surface of a semiconductor substrate. Source and drain regions are formed in the semiconductor substrate in alignment with the gate region and an enhanced doping sub-surface impurity region is formed in the semiconductor substrate using the mask as a doping mask. A gate electrode is then formed overlying the semiconductor substrate in alignment with the gate region by using the mask as a gate alignment mask.

### TECHNICAL FIELD

The present invention generally relates to semiconductor devices and to methods for their fabrication, and more particularly relates to MOS semiconductor devices and to methods for fabricating such devices with a selectively formed channel region.

### BACKGROUND

The majority of present day integrated circuits (ICs) are implemented by using a plurality of interconnected field effect transistors (FETs) also called metal oxide semiconductor field effect transistors (MOSFETs), or simply MOS transistors. An MOS transistor includes a gate electrode as a control electrode and spaced apart source and drain regions formed in a semiconductor substrate and between which a current can flow. A control voltage applied to the gate electrode controls the flow of current through a channel between the source and drain regions.

The fabrication of integrated circuits faces a number of competing challenges. As the functions implemented in an integrated circuit (IC) become more complex, more and more MOS transistors must be incorporated on the integrated circuit chip. In addition to the trend toward more complex integrated circuits, there is also a trend toward faster integrated circuits. That is, the trend is toward reducing the switching speed of the integrated circuits.

As the number of transistors on the IC increases, there is a need to reduce the size of each individual transistor and hence the size of the components that make up the transistor. Reducing the size of an MOS transistor requires decreasing the spacing between the source and drain regions, but decreasing the source-drain spacing can incur problems with short channel effects as well as punch through breakdown. Typical solutions for these problems include halo implants to combat short channel effects and punch through implants to increase the doping in the channel and substrate well to avoid punch through. These solutions, however, lead to other problems.

Junction capacitance, that is, the capacitance of the source-substrate junction and especially the drain-substrate junction, in large part determines the speed of the IC as these capacitances must be charged or discharged during a switching operation. Junction capacitance is increased by increasing the impurity doping of the material on either side of the junction. Typical halo implants, threshold adjust implants, and punch through implants increase the impurity doping in the substrate well and channel and thus increase the junction capacitance and adversely affect switching speed.

One considered approach has been to lower the impurity doping in the substrate well to reduce the junction capacitance by increasing the dose of the punch through implant and placing the implant deeper in the channel region. In conventional MOS processing, however, the threshold adjust and punch through implants are introduced over the entire active area of the transistor, including the channel region and the source and drain regions. Thus placing the punch through implant deeper in the channel region effectively places it under the source and drain regions thereby increasing, not decreasing, the junction capacitance. Such an approach thus is not a workable solution.

In addition to the issue of junction capacitance, the increased doping concentration under the source/drain extension regions results in increased band-band leakage currents (also called Gate induced Drain Leakage or GIDL). This leakage current establishes a floor below which the leakage current cannot be reduced, and therefore establishes the static power consumption of a technology and of devices built on that technology. In order to reduce the leakage current, one has to improve the short channel characteristics of the device without increasing the punch through or halo doping under the source/drain extension regions.

Accordingly, a need exists to provide methods for fabricating an integrated circuit having decreased source-drain spacing of MOS transistors of that integrated circuit without adversely affecting the IC switching speed. Additionally it is desirable to provide an MOS transistor capable of switching speeds necessary for integrated circuit implementation. Still further, it is desirable to provide an MOS transistor and methods for fabricating such a transistor that has good short channel control with minimal halo or source drain doping, low junction capacitance, and low band to band leakage current, Furthermore, other desirable features and characteristics of the present invention will become apparent from the subsequent detailed description and the appended claims, taken in conjunction with the accompanying drawings and the foregoing technical field and background.

### BRIEF SUMMARY

In accordance with one embodiment a method for fabricating an MOS device is provided that includes depositing a layer of dummy gate material overlying a surface of a semiconductor substrate and patterning the dummy gate material to form a dummy gate. Spaced apart source and drain regions are implanted in alignment with the dummy gate and a gap fill material is deposited overlying the semiconductor substrate and the dummy gate. A portion of the gap fill material is removed to expose a top surface of the dummy gate and the dummy gate is removed to form a recess extending through the gap fill material. Conductivity determining ions are implanted through the recess and into the semiconductor substrate to form an impurity doped channel region between the spaced apart source and drain regions. A portion of the surface of the semiconductor substrate overlying the impurity doped channel is exposed and a gate insulator and gate electrode are formed overlying the portion of the surface.

In accordance with a further embodiment a method for fabricating an MOS device is provide that includes forming a mask defining a gate region overlying a surface of a semiconductor substrate. Source and drain regions are formed in the semiconductor substrate in alignment with the gate region and an enhanced doping sub-surface impurity region is formed in the semiconductor substrate using the mask as doping mask. A gate electrode is then formed overlying the semiconductor substrate in alignment with the gate region by using the mask as a gate alignment mask.

In accordance with yet another embodiment an MOS device is provided that includes a gate electrode overlying a semiconductor substrate with spaced apart source and drain regions formed in the semiconductor substrate and aligned with the gate electrode. An impurity doped channel region underlies the gate electrode and is spaced apart from the source and drain regions.

### BRIEF DESCRIPTION OF THE DRAWINGS

The present invention will hereinafter be described in conjunction with the following drawing figures, wherein like numerals denote like elements, and wherein

FIG. 1 depicts graphically the impurity doping found in the well or substrate region underlying the gate electrode of a conventional MOS device; and

FIGS. 2-10 illustrate, in cross sectional views, a portion of an MOS integrated circuit device and methods for its fabrication in accordance with various embodiments.

### DETAILED DESCRIPTION

The following detailed description is merely exemplary in nature and is not intended to limit the invention or the application and uses of the invention. Furthermore, there is no intention to be bound by any expressed or implied theory presented in the preceding technical field, background, brief summary or the following detailed description.

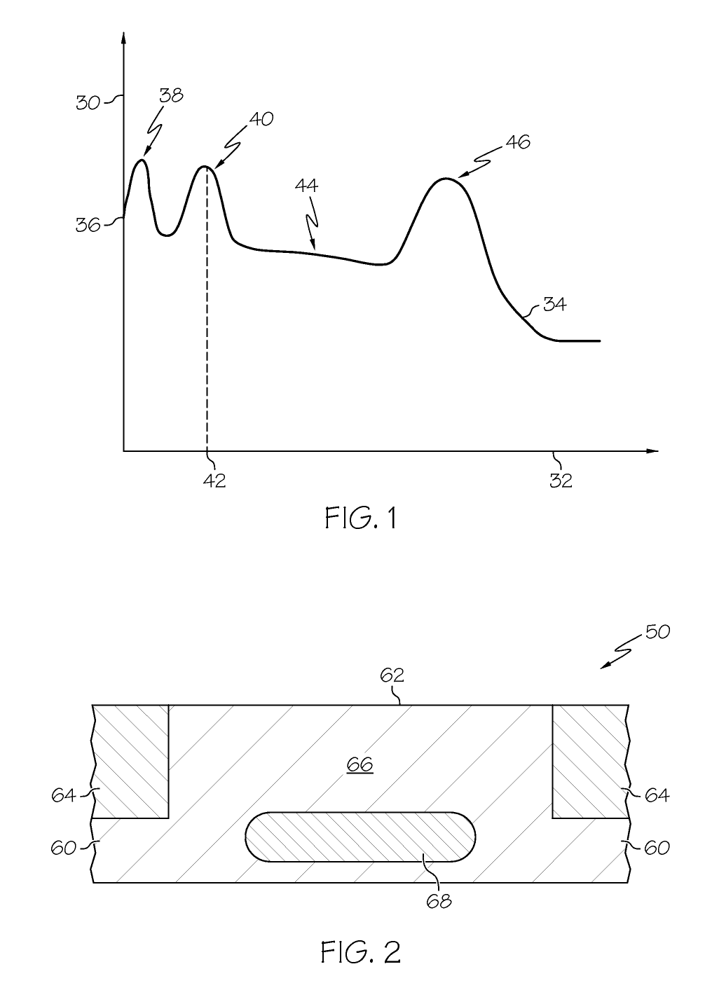

FIG. 1 depicts graphically the impurity doping found in the well or substrate region underlying the gate electrode of a conventional MOS device and illustrates the problem attendant with such a conventional structure. Vertical axis 30 represents impurity doping concentration in the well region and horizontal axis 32 represents increasing distance away from the substrate surface. Graphical line 34 illustrates that the impurity doping concentration increases from the value 36 at the substrate surface to a peak value 38 at a near sub-surface location. The peak value 38 represents the impurity doping concentration resulting from a threshold adjust ion implantation. Further into the well region the impurity doping concentration decreases from the peak value 38 and then increases again to a new peak value 40 that represents the impurity doping concentration resulting from an ion implantation designed to combat punch through conditions (a punch through implant). The peak value 40 of the punch through ion implantation is found at a location 42 that corresponds to the junction depth (xⱼ) of the source and drain regions. The punch through implant, located to correspond to the source/drain junction depth, is thus located at the depth to be most problematic in regard to increased junction capacitance. The impurity doping concentration decreases below the punch through ion implant concentration to the normal well impurity doping concentration 44 and then may increase again as illustrated at 46 if a buried layer is used under the well. A buried layer is sometimes used, especially in CMOS circuits to protect against latch-up.

FIGS. 2-10 illustrate, in cross sectional views, a portion of an MOS integrated circuit device 50 and various embodiments for its fabrication that avoid the problems with an impurity doping distribution as depicted above. The portion of IC device 50 that is illustrated is a single MOS transistor. In accordance with the various embodiments to be described, the single transistor can be either an n-channel MOS transistor or a p-channel transistor, but will be described, for illustrative purposes only, as an n-channel transistor. The complete IC can include n-channel transistors, p-channel transistors, or can be a CMOS IC including both types. The described embodiments can be applied to any or all of the transistors of the IC.

Various steps in the manufacture of MOS transistors are well known and so, in the interest of brevity, many conventional steps will only be mentioned briefly herein or will be omitted entirely without providing the well known process details. Although the term “MOS device” properly refers to a device having a metal gate electrode and an oxide gate insulator, that term will be used throughout to refer to any semiconductor device that includes a conductive gate electrode (whether metal or other conductive material) that is positioned over a gate insulator (whether oxide or other insulator) which, in turn, is positioned over a semiconductor substrate.

The method for fabricating IC device 50 in accordance with one embodiment begins, as illustrated in FIG. 2 by providing a semiconductor substrate 60 having a surface 62. The semiconductor substrate can be silicon, silicon admixed with germanium, or other semiconductor material commonly used in the semiconductor industry. Isolation regions 64 such as shallow trench isolation (STI) are formed in the semiconductor substrate, extend into the substrate from the surface, and serve to aid in defining a well region 66. Isolation regions 64 provide electrical isolation between devices formed in well region 66 and devices formed in adjacent well regions. Although not used in all ICs, a buried layer 68 may be formed underlying the well region. For an n-channel MOS transistor the well region is impurity doped p-type. In accordance with one embodiment the starting semiconductor substrate is a lightly impurity doped p-type wafer in which a p-type well region of the proper impurity doping concentration is formed by ion implantation. Although not illustrated, a similar n-type well region could be formed by ion implantation to accommodate the fabrication of p-channel transistors. In an alternate embodiment a well region 66 could be formed by epitaxially growing a layer of semiconductor material overlying buried layer 68 and doping the well region by out diffusion from the buried layer. One or more ion implantations can be used, if necessary, to tailor the impurity doping concentration in well 66.

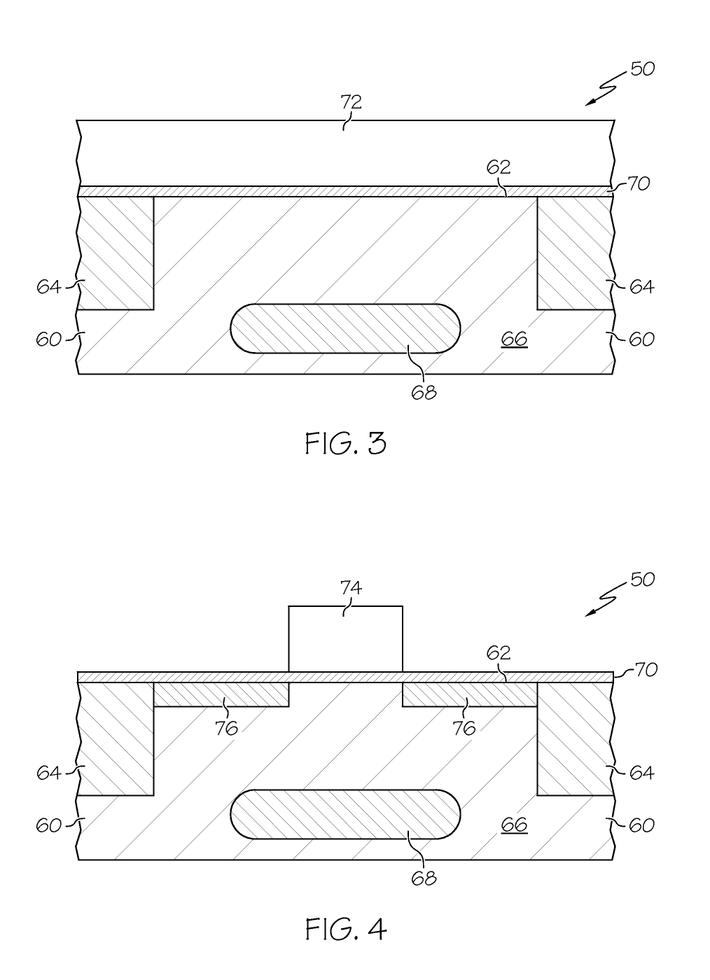

In accordance with one embodiment the method of fabricating a semiconductor device continues by forming a thin insulating layer 70 on surface 62 as illustrated in FIG. 3. A layer of dummy gate material 72 such as a layer of polycrystalline silicon is deposited over the thin insulating layer.

As illustrated in FIG. 4, the method continues by patterning the layer of dummy gate material to form a dummy gate 74. The dummy gate can be formed by conventional photolithographic patterning and anisotropic etching, for example by reactive ion etching (RIE). In accordance with one embodiment source and drain extensions 76 are formed by ion implanting n-type conductivity determining ions such as arsenic ions into the surface of the well region using the dummy gate as an ion implantation mask. The source and drain extensions are thus self aligned to the dummy gate.

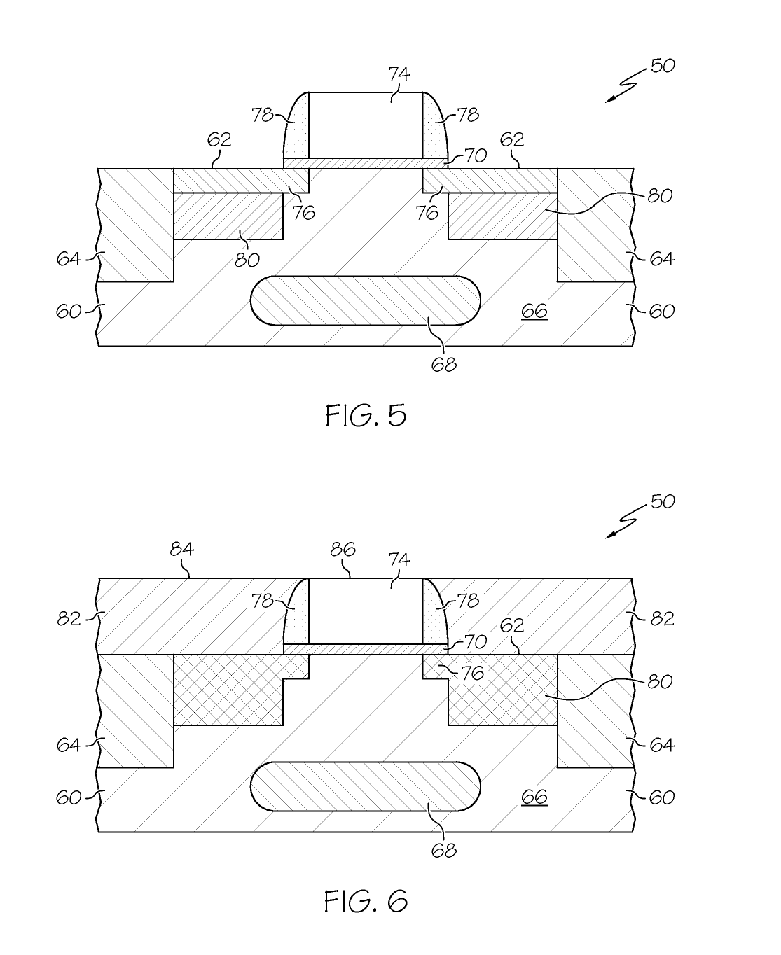

In accordance with an embodiment sidewall spacers 78 are formed on the edges of dummy gate 74 as illustrated in FIG. 5. The sidewall spacers can be formed, for example, by depositing a layer of dielectric material such as an oxide or a nitride overlying the dummy gate. The dielectric material is anisotropically etched with the anisotropic etching continuing to etch the exposed portion of thin insulating layer 70. Deep source and drain regions 80 are formed by ion implanting n-type conductivity determining ions such as arsenic or phosphorous ions into the surface of well region 66 using the dummy gate and the sidewall spacers as an ion implantation mask. The deep source and drain regions are thus self aligned to the sidewall spacers and also self aligned to and spaced apart from the dummy gate. The device structure is thermally annealed, for example by a rapid thermal anneal (RTA), to activate the implanted source and drain implanted ions.

A layer of gap fill material 82 is deposited overlying dummy gate 74 and surface 62 of substrate 60. The layer of gap fill material can be, for example, a layer of dielectric material and should be a material different than the dummy gate material. The layer of gap fill material is planarized, for example by chemical mechanical planarization (CMP), to provide a planar upper surface 84 to the layer of gap fill material and to expose the top surface 86 of dummy gate 74 as illustrated in FIG. 6.

Although this description of the various embodiments is focused on the fabrication of only an n-channel MOS transistor, those of skill in the art will understand that while the source and drain impurity doping process steps illustrated above have been carried out, a layer of masking material could be applied to cover and protect p-channel devices that may be part of the intended IC. After the n-type source and drain regions have been completed that masking layer could be removed and another masking layer applied to cover and protect the n-channel devices. The p-channel devices could then be processed in a manner similar to that described for the n-channel devices with an obvious change in impurity doping type. The thermal anneal to activate the implanted ions can be carried out either after each of the device types is implanted or after both of the device types receives the source and drain implants.

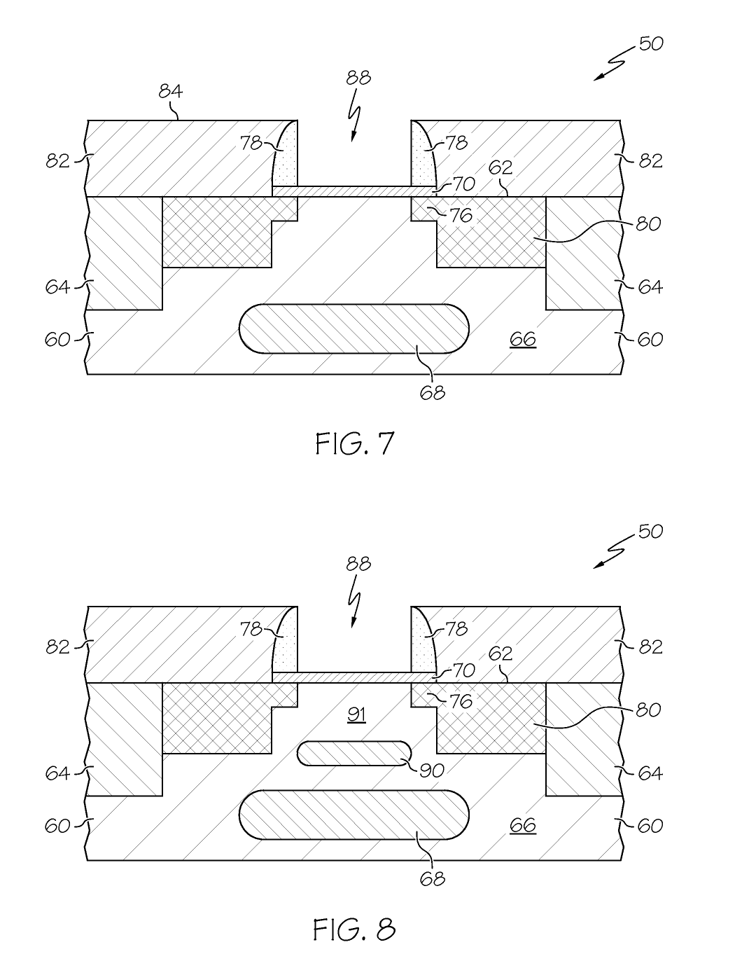

After removing any protective masking layer that may have been placed over the re-channel devices during the processing of p-channel devices, the method in accordance with an embodiment proceeds as illustrated in FIG. 7. Dummy gate 74 is removed to form a recess 88 extending through the layer of gap fill material 82. The dummy gate can be etched by either a wet etch or a plasma etch using an etch chemistry that etches the dummy gate material in preference to the gap fill material.

In accordance with an embodiment of the method to fabricate a semiconductor device, a localized punch through and threshold adjust ion implantation is performed. Conductivity determining ions are implanted through recess 88 and into a localized sub-surface region 90 of well region 66 using the layer of gap fill material and the sidewall spacers as an implantation mask as illustrated in FIG. 8. The implanted ions are selected to increase the conductivity of well region 66 in region 90. For the n-channel MOS transistor being described, p-type dopant ions are selected. The implanted ions can be, for example, ions of boron. The energy of the implanted ions can be selected to adjust the range of the implanted distribution peak at any desired depth below surface 62. For example, the peak of the implanted ion distribution can be located at a depth below the surface of between 25 and 50 nanometers (nm). Because the ions are implanted through recess 88 formed by removing dummy gate 74, localized sub-surface region 90 is self aligned to the original location of the dummy gate and is located selectively in the channel region 91 alone. In addition, because the source and drain regions (76 and 80) were aligned to the dummy gate, the localized sub-surface region 90 is self aligned to the source and drain regions and is spaced apart from those regions. Localized sub-surface region 90 is spaced below source and drain extensions 76 and laterally spaced apart from deep source and drain regions 80. The implantation of region 90 is done after most of the thermal processing steps used in fabricating device 50 have been completed, such as the source and drain implant anneals, so there will be little subsequent thermal diffusion of the implanted ions in region 90.

Although not illustrated in the FIGURES, in accordance with a further embodiment localized sub-surface region 90 also can be formed as follows. Following the formation of recess 88 as illustrated in FIG. 7, gap fill material 82 and sidewall spacers are used as an etch mask to first remove the exposed portion of thin insulating layer 70 and then to etch a shallow recess into the surface of semiconductor substrate 60. The shallow recess can be etched, for example, to a depth of about 25 nm. Region 90 can be implanted at the surface of the shallow recess by a low energy ion implantation. After implanting region 90 an undoped layer of silicon is epitaxially grown in the recess in the surface of semiconductor substrate 60 by a process of selective epitaxial growth to bury region 90 and to substantially restore the surface of semiconductor substrate 60. The selective epitaxial growth can be performed at a low temperature so as not to substantially redistribute the implanted ions by thermal diffusion. Selective epitaxial growth is a process, as is well known to those of skill in the art, in which epitaxial growth process conditions are adjusted to cause the epitaxial growth to occur only on exposed crystalline material, in this case only in the recess formed in semiconductor substrate 60.

Regardless of the manner in which sub-surface region 90 is formed, because the increased impurity doping in the localized sub-surface region 90 does not directly abut either the source or the drain region, the localized sub-surface region does not increase the source-substrate nor the drain-substrate capacitance and hence does not decrease the switching speed of the device and does not increase band-band leakage. As positioned, however, the localized sub-surface region of increased impurity doping is effective in reducing short channel effects and punch through related problems without increasing halo or source drain doping.

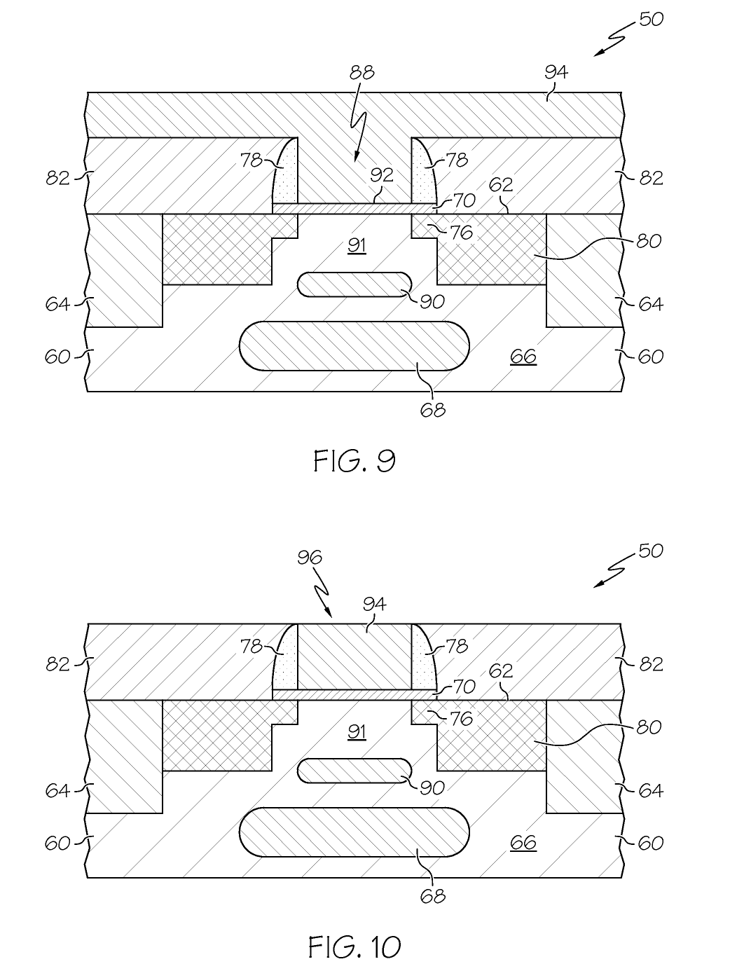

Following the formation of the localized sub-surface region 90 in the channel region, the surface of the well region at the bottom of recess 88 is etched and cleaned. A gate insulator layer 92 is formed on surface 62 of well region 66 at the bottom of recess 88 as illustrated in FIG. 9. The gate insulator layer is overlaid by a deposited layer or layers of gate electrode material 94. In accordance with one embodiment the gate insulator layer is or includes a high dielectric constant (high k) insulator. Gate insulator 92 can be, for example, a layer of thermally grown silicon dioxide, perhaps admixed with nitrogen, overlaid by a layer of a hafnium oxide or other high k dielectric material. The composite gate insulator is a high k insulator as it has a dielectric greater than the dielectric constant of silicon dioxide alone. The gate electrode material can be, for example, a layer of metal overlaid by a layer of polycrystalline silicon. The layer of metal can be selected, as well known by those of skill in the art, to effect a proper threshold voltage for the MOS device being fabricated. In accordance with an alternate embodiment gate insulator layer 92 can be, for example, a layer of thermally grown silicon dioxide and gate electrode material 94 can be a layer of polycrystalline or amorphous silicon.

After the deposition of gate electrode material 94 the device structure is planarized, for example by CMP, to remove the excess gate electrode material overlying the layer of gap fill material 82 as illustrated in FIG. 10. The planarization completes the formation of a gate electrode 96 positioned overlying channel region 91 and localized sub-surface region 90.

If a CMOS device is being fabricated, a localized sub-surface region impurity doped with n-type dopant ions could be formed in the channel of the p-channel devices in a manner similar to the formation of region 90 for the n-channel devices. The gate dielectric and gate electrode for the p-channel device is formed in similar manner as for the n-channel device with appropriate changes to set the threshold voltages for the different device types. A different metal will likely be chosen for the gate electrode material of the p-channel device than for the n-channel device.

As will be well understood by those of skill in the art, device 50 can be completed by conventional middle of line and back end of line processing steps. Those processing steps may include, for example, etching contact opening through the layer of gap fill material to expose surface areas of the source and drain regions, forming silicide and/or metal contacts extending into the contact openings to the surfaces areas, forming conductive device interconnects, depositing interlayer dielectrics, and the like.

While at least one exemplary embodiment has been presented in the foregoing detailed description, it should be appreciated that a vast number of variations exist. It should also be appreciated that the exemplary embodiments are only examples, and are not intended to limit the scope, applicability, or configuration of the invention in any way. Rather, the foregoing detailed description will provide those skilled in the art with a convenient road map for implementing the exemplary embodiments. It should be understood that various changes can be made in the size, spacing and doping of elements without departing from the scope of the invention as set forth in the appended claims and the legal equivalents thereof.

What is claimed is:

1. A method for fabricating an MOS device comprising:
depositing a layer of dummy gate material overlying a surface of a semiconductor substrate and patterning the dummy gate material to form a dummy gate;
implanting spaced apart source and drain regions in alignment with the dummy gate;
depositing a gap fill material overlying the semiconductor substrate and the dummy gate;
removing a portion of the gap fill material to expose a top surface of the dummy gate;
removing the dummy gate to form a recess extending through the gap fill material;
implanting conductivity determining ions through the recess and into the semiconductor substrate to form an impurity doped channel region between the spaced apart source and drain regions;
exposing a portion of the surface of the semiconductor substrate overlying the impurity doped channel; and
forming a gate insulator and gate electrode overlying the portion of the surface.

2. The method of claim 1 wherein depositing a layer of dummy gate material comprises depositing a layer of polycrystalline silicon.

3. The method of claim 1 further comprising forming sidewall spacers on the dummy gate.

4. The method of claim 3 wherein implanting spaced apart source and drain regions comprises:
implanting source and drain extensions in alignment with the dummy gate; and implanting deep source and drain regions in alignment with the sidewall spacers.

5. The method of claim 1 wherein depositing a gap fill material comprises depositing a dielectric material and wherein removing a portion of the gap fill material comprises chemical mechanical planarization.

6. The method of claim 1 wherein implanting conductivity determining ions comprises implanting ions into the semiconductor substrate with a peak dopant concentration at between 25-50 nm below the surface.

7. The method of claim 6 wherein implanting conductivity determining ions comprises implanting ions of a type to locally increase the conductivity of the substrate.

8. The method of claim 1 wherein forming a gate insulator and gate electrode comprises depositing a high dielectric constant insulator material and an overlying metal layer.

9. The method of claim 8 further comprising subjecting the overlying metal layer to a chemical mechanical planarization.

10. A method for fabricating an MOS device comprising:
forming a mask defining a gate region overlying a surface of a semiconductor substrate;
forming source and drain regions in the semiconductor substrate in alignment with the gate region;
forming an enhanced doping sub-surface impurity region in the semiconductor substrate using the mask as a doping mask; and
forming a gate electrode overlying the semiconductor substrate and in alignment with the gate region using the mask as a gate alignment mask.

11. The method of claim 10 wherein forming a mask comprises:
depositing a layer of dummy gate material;
patterning the layer of dummy gate material;
forming sidewall spacers on the patterned layer of dummy gate material;
depositing a layer of gap fill material overlying the patterned layer of dummy gate material;
removing a portion of the gap fill material to expose a top portion of the patterned layer of dummy gate material; and
removing the patterned layer of dummy gate material.

12. The method of claim 11 wherein forming source and drain regions comprises forming a first region in alignment with the patterned layer of dummy gate material and forming a second region in alignment with the sidewall spacers.

13. The method of claim 10 wherein forming an enhanced doping sub-surface impurity region comprises implanting conductivity determining ions chosen to increase the conductivity of the sub-surface impurity region using the mask as an ion implantation mask.

14. The method of claim 13 wherein ion implanting conductivity determining ions comprises implanting ions having a range selected to place a peak concentration of the sub-surface impurity region 25-50 nm below the surface.

15. The method of claim 10 wherein forming an enhanced doping sub-surface impurity region comprises:
etching a recess into the surface of the semiconductor substrate using the mask as an etch mask;
doping the semiconductor substrate at the bottom of the recess using the mask as a doping mask; and
epitaxially growing a layer of substantially undoped semiconductor material to fill the recess.

16. The method of claim 15 wherein the step of doping the semiconductor material comprises ion implanting the semiconductor substrate using the mask as an ion implantation mask.

17. The method of claim 10 wherein forming a gate electrode comprises:
cleaning a portion of the surface exposed by the mask;
depositing a layer of gate insulator material overlying the surface;
depositing a layer of gate electrode material overlying the layer of gate insulator material; and
removing gate electrode material overlying the mask.

18. The method of claim 17 wherein depositing a layer of gate insulator material comprises depositing a layer of high dielectric constant insulator material and wherein depositing a layer of gate electrode material comprises depositing a layer of metal.

19. The method of claim 10 further comprising etching a recess into the surface of the semiconductor substrate using the mask as an etch mask to recess the surface in the gate region.

20. An MOS device comprising:
a gate electrode overlying a semiconductor substrate;
spaced apart source and drain regions formed in the semiconductor substrate and aligned with the gate electrode; and
an impurity doped channel region underlying the gate electrode and spaced apart from the source and drain regions.
